(19) United States
(12) Patent Application Publication
(10) Pub. No.: US 2008/0237664 A1
(43) Pub. Date: Oct. 2, 2008

(54) SEMICONDUCTOR DEVICE AND METHOD OF DRIVING THE SAME

(75) Inventors: Kyong-Hee JOO, Gyeonggi-do (KR); In-Seok YEO, Seoul (KR); Chang-Rok MOON, Seoul (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 11/866,339

(22) Filed: Oct. 2, 2007

(30) Foreign Application Priority Data
Oct. 2, 2006 (KR) 10-2006-97299

(51) Int. Cl. H01L 31/113

(52) U.S. Cl. 257/290; 257/E31.085

(57) ABSTRACT

Provided are a semiconductor device and a method of driving the semiconductor device. The semiconductor device includes an optical reaction transistor. The optical reaction transistor includes a semiconductor substrate, a tunnel insulation layer formed on the semiconductor substrate, an optical reaction layer formed on the tunnel insulation layer, a blocking insulation layer formed on the optical reaction layer, and a gate electrode formed on the blocking insulation layer.

### CROSS-REFERENCE TO RELATED APPLICATIONS

This U.S. non-provisional patent application claims priority under 35 U.S.C. § 119 to Korean Patent Application No. 10-2006-97299, filed on Oct. 2, 2006, the contents of which are hereby incorporated by reference in their entirety.

### BACKGROUND

1. Technical Field

The present invention relates to a semiconductor device and a method of driving the semiconductor device, and more particularly, to a semiconductor device including an optical reaction layer and a method of driving the semiconductor device.

2. Description of the Related Art

Some examples of semiconductor devices include image sensors and nonvolatile memory devices. The image sensors are used to convert an optical signal into an electrical signal. The image sensors can be classified into a complementary metal oxide semiconductor (CMOS) image sensor and a charge-coupled device (CCD) image sensor. The CMOS image sensor includes a pixel unit. The pixel unit includes a photodiode and three or four transistors. The photodiode receives light and generates image signals in response to the light, and the transistors control image signals generated by the photodiode. Since the pixel unit includes three or four transistors, it is difficult to reduce the size of the pixel unit.

A flash memory device, a type of nonvolatile memory device, is a highly integrated device having the advantages of both an erasable programmable read only memory (EPROM) and an electrically erasable programmable read only memory (EEPROM). However, when data is retained in the flash memory device, undesirable current leakage can occur from a charge trap layer to a semiconductor substrate or a gate electrode. This can reduce the data retention capability of the device. Further, the charge trap layer of the flash memory device must provide a wide memory window and rapid programming/erasing characteristics in order to meet current device requirements. Thus, there is a need for a nonvolatile memory device including a charge trap layer having good physical and electrical characteristics.

### SUMMARY

The present invention provides a highly integrated semiconductor device and a method of driving the semiconductor device. The present invention also provides a semiconductor device including a charge trap layer having good characteristics, and a method of driving the semiconductor device.

Embodiments of the present invention provide semiconductor devices including an optical reaction transistor, wherein the optical reaction transistor includes: a semiconductor substrate; a tunnel insulation layer formed on the semiconductor substrate; an optical reaction layer formed on the tunnel insulation layer; a blocking insulation layer formed on the optical reaction layer; and a gate electrode formed on the blocking insulation layer.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIGS. 1 and 2 are cross-sectional views illustrating semiconductor devices according to embodiments of the present invention;

FIG. 3 is a graph for comparing energy bands of various materials that may be used in a semiconductor device;

FIG. 4 is a graph for comparing the endurance of a semiconductor device for the cases where Si₃N₄ and GaN are used for a charge trap layer of the semiconductor device, respectively;

FIG. 5 is an energy band diagram for explaining a method of programming a semiconductor device according to an embodiment of the present invention;

FIG. 6 is a graph showing a relationship between a threshold voltage and a programming voltage of a semiconductor device according to an embodiment of the present invention;

FIG. 7 is an energy band diagram for explaining a method of erasing data from a semiconductor device according to an embodiment of the present invention;

FIG. 8 is a graph showing a relationship between a threshold voltage and an erasing voltage of a semiconductor device according to an embodiment of the present invention;

FIG. 9 is a graph showing tunneling current curves for the cases where a semiconductor device is illuminated and not illuminated, respectively;

FIGS. 10 and 11 are graphs showing tunneling current curves for the case where an optical reaction layer is formed of GaN and the case where an optical reaction layer is formed of ZnO, respectively;

FIG. 12 is a graph illustrating an optical absorbance of an optical reaction layer formed of GaN with respect to wavelengths of light according to an embodiment of the present invention;

FIG. 13 is a graph illustrating capacitance-voltage (C-V) curves of a GaN optical reaction layer according to an embodiment of the present invention;

FIGS. 14A through 14D are graphs illustrating variations in threshold voltage with respect to wavelengths of light illuminated on a semiconductor device; and

FIGS. 15A and 15B are graphs for explaining variations in threshold voltage with respect to the intensity of light illuminated on a semiconductor device.

### DETAILED DESCRIPTION

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

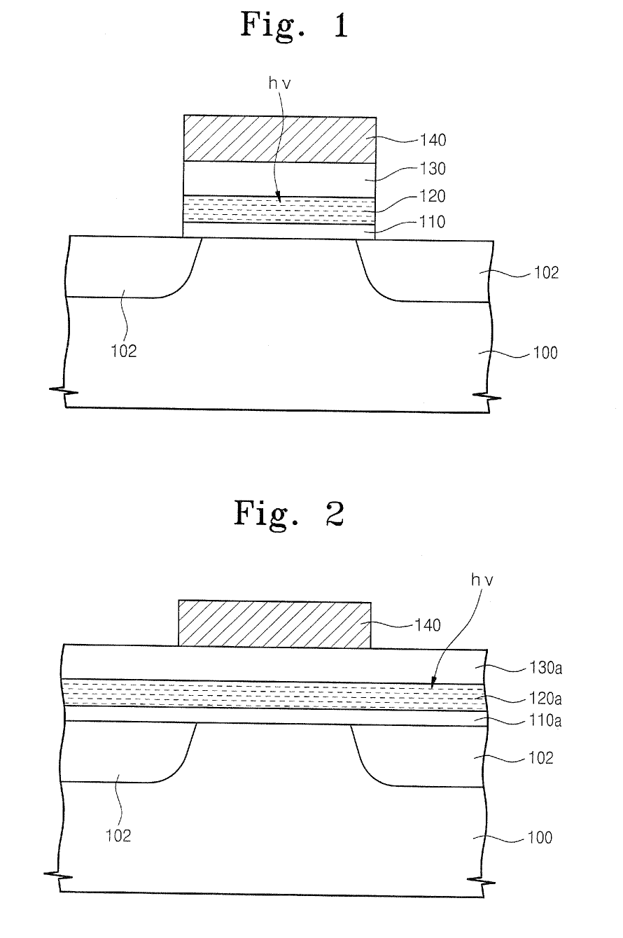

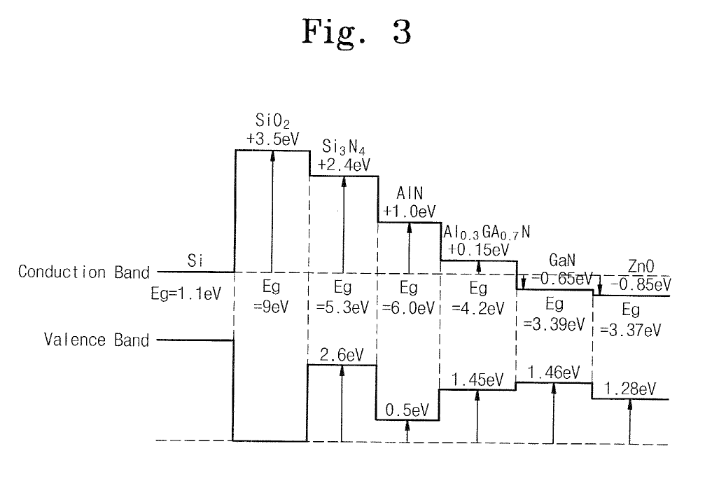

FIGS. 1 and 2 are cross-sectional views illustrating semiconductor devices according to embodiments of the present invention, and FIG. 3 is a graph for comparing energy bands of various materials that may be used in a semiconductor device;

Referring to FIG. 1, a tunnel insulation layer 110 is formed on a semiconductor substrate 100. The tunnel insulation layer 110 may include a silicon oxide (SiO₂) layer. The tunnel insulation layer 110 may have a thickness in the range from about 3.5 nm to about 5.5 nm. The tunnel insulation layer 110 may have a conduction band higher in energy than a conduction band of the semiconductor substrate 100 by about 3.5 eV. Therefore, the tunnel insulation layer 110 has an electron affinity less than that of the semiconductor substrate 100. The electron affinity is the energy required to excite an electron to the vacuum level.

An optical reaction layer 120 is formed on the tunnel insulation layer 110. The optical reaction layer 120 may include a photoreactive charge trap layer. The optical reaction layer 120 includes a material having an electron affinity greater than that of the semiconductor substrate 100. For example, the optical reaction layer 120 may include GaN or ZnO. Referring to FIG. 3, GaN may have a conduction band lower in energy than that of the semiconductor substrate 100 by about 0.65 eV. ZnO may have a conduction band lower in energy than that of the semiconductor substrate 100 by about 0.85 eV. On the other hand, Si₃N₄ has a conduction band higher in energy than that of Si by about 2.4 eV. Therefore, a charge trap layer formed using GaN or ZnO has a deeper quantum well structure than a charge trap layer formed using Si₃N₄. A material such as GaN or ZnO having a conduction band lower than that of the semiconductor substrate 100 can be defined as a negative conduction band offset (NCBO) material. That is, NCBO materials have an electron affinity greater than that of the semiconductor substrate 100.

The optical reaction layer 120 may have a long data retention time. The reason for this is that electrons can be confined by a deep energy level since the optical reaction layer 120 has a conduction band lower than that of the semiconductor substrate 100. The optical reaction layer 120 may have a thickness in the range of about 4 nm to about 10 nm. The optical reaction layer 120 may have a thin film shape or nano crystal structure.

A blocking insulation layer 130 is formed on the optical reaction layer 120. The blocking insulation layer 130 may be formed using SiO₂, HfO, ZrO, LaAlO, or AlO. The blocking insulation layer 130 may have a thickness in the range of about 10 nm to about 20 nm. A gate electrode 140 is formed on the blocking insulation layer 130. The gate electrode 140 may include a light-transmissive material. Light hv transmitted to the optical reaction layer 120 through the light-transmissive material of the gate electrode 140 may cause electron-hole pairs (EHPs) to be generated in the optical reaction layer 120. As an example, the light-transmissive material may be a transparent and conductive material such as indium tin oxide (ITO) or ZnO. When the light-transmissive material is ZnO, the gate electrode 140 may be an n-type gate electrode. A pair of impurity regions 102 can be formed in regions of the semiconductor substrate 100 that are adjacent to the tunnel insulation layer 110. The tunnel insulation layer 110, the optical reaction layer 120, the blocking insulation layer 130, the gate electrode 140, and the impurity regions 102 form an optical reaction transistor. A plurality of such optical reaction transistors may be arranged in the semiconductor device, and neighboring optical reaction transistors may share the impurity regions 102.

Referring to FIG. 2, an optical reaction layer 120a can extend above a semiconductor substrate 100 under a gate electrode 140. In the current embodiment, the optical reaction layer 120a has a wider area than the optical reaction layer 120 of the previous embodiment shown in FIG. 1. A blocking insulation layer 130a and a tunnel insulation layer 110a are formed on top and bottom surfaces of the optical reaction layer 120a. The blocking insulation layer 130a and the tunnel insulation layer 110a are disposed between the semiconductor substrate 100 and the gate electrode 140 and have wider areas than the blocking insulation layer 130 and the tunnel insulation layer 110 shown in FIG. 1. In this case, the gate electrode 140 might not include a light-transmissive material.

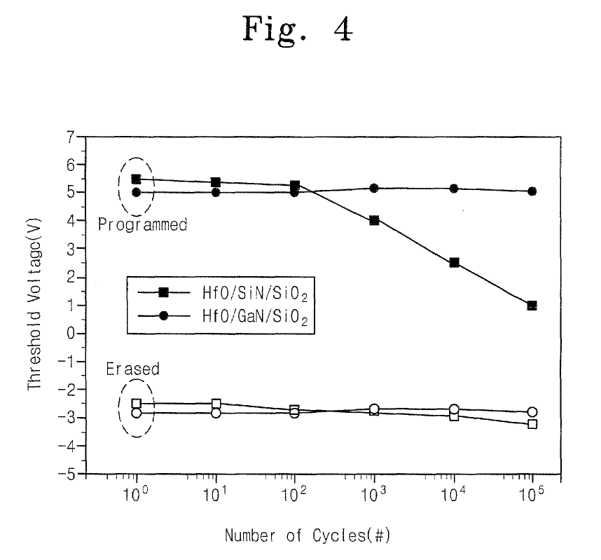

FIG. 4 is an endurance graph illustrating programming and erasing characteristics of a semiconductor device for comparing the case where Si₃N₄ is used for a charge trap layer of the semiconductor device with the case where GaN is used for the charge trap layer of the semiconductor device. Referring to FIG. 4, the horizontal axis denotes the number of programming or erasing cycles, and the vertical axis denotes a threshold voltage. A silicon oxide layer having a thickness of 35 Å is used as a tunnel insulation layer, a hafnium oxide layer having a thickness of 200 Å is used as a blocking insulation layer, and an aluminum layer is used as a gate electrode. Although Si₃N₄ is conventionally used for the charge trap layer of a semiconductor device, GaN is used for the charge trap layer of the semiconductor device according to some embodiments of the invention. In this case, the threshold voltage of the semiconductor device does not vary even after 10⁵ or more programming/erasing cycles, as compared to the Si₃N₄ device which begins to show degradation after about 10² cycles. The reason for this is that GaN provides a deeper quantum well structure than Si₃N₄.

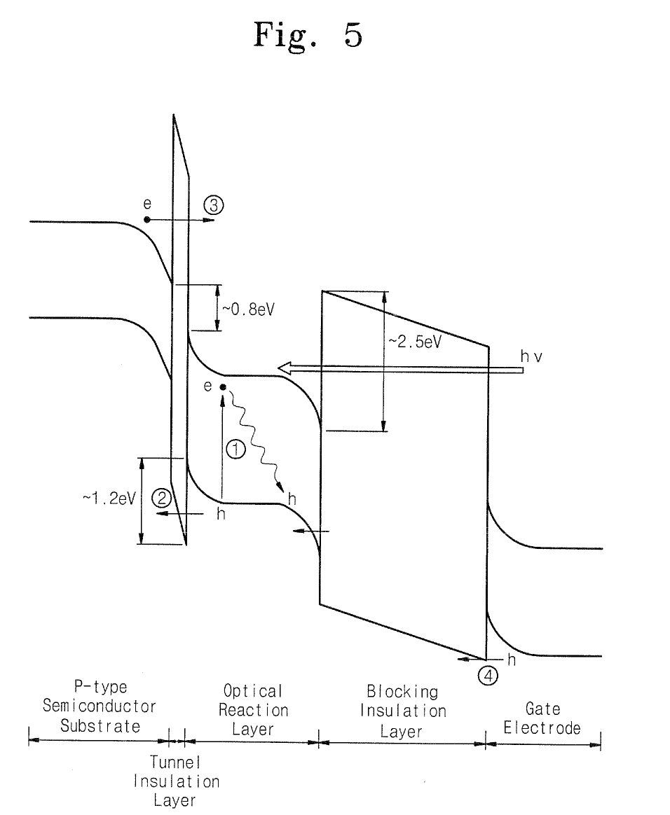

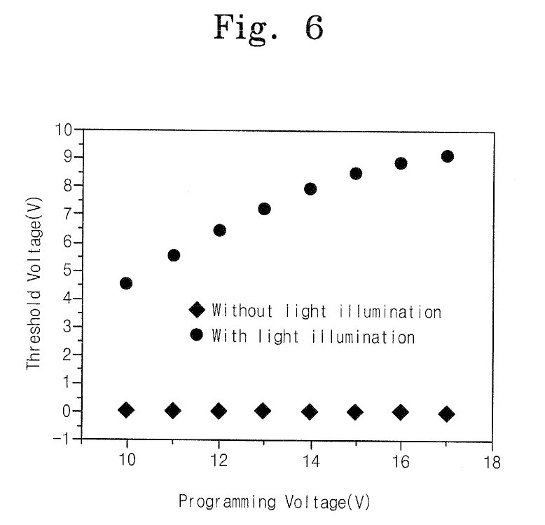

FIG. 5 is an energy band diagram for explaining a method of programming a semiconductor device according to an embodiment of the present invention. Referring to FIG. 5, an optical reaction transistor of the semiconductor device includes a p-type semiconductor substrate, a tunnel insulation layer formed on the p-type semiconductor substrate, an optical reaction layer formed on the tunnel insulation layer, a blocking insulation layer formed on the optical reaction layer, and a gate electrode formed on the blocking insulation layer. For example, the optical reaction layer may be formed of ZnO. The optical reaction layer has a conduction band lower than that of the p-type semiconductor substrate by about 0.8 eV. For example, the tunnel insulation layer may be formed of SiO₂, the blocking insulation layer may be formed of HfO, and the gate electrode may be formed of an n-type ZnO layer. A programming voltage is applied to the gate electrode of the optical reaction transistor.

When the optical reaction transistor is exposed to light hv, pairs of electrons (e) and holes (h) are generated in the optical reaction layer (\textcircled{1}). Due to a low barrier potential (about 1.2 eV), the holes (h) tend to escape from the optical reaction layer to the p-type semiconductor substrate (\textcircled{2}) due to the programming voltage (a positive voltage) applied to the gate electrode. On the other hand, it is difficult for the electrons (e) to escape from the optical reaction layer to the gate electrode due to a relatively high barrier potential (about 2.5 eV) and a large thickness of the blocking insulation layer. The programming voltage can be adjusted to allow the holes (h) to escape from the optical reaction layer to the p-type semiconductor substrate by tunneling, but not to allow the electrons (e) to escape from the optical reaction layer to the gate electrode by tunneling. Meanwhile, electrons (e) existing in the p-type semiconductor substrate can be moved to the optical reaction layer by tunneling caused by the programming voltage (\textcircled{3}). Holes (h) can be moved from the gate electrode to the optical reaction layer by tunneling (\textcircled{4}). The electrons (e) and the holes (h) moved to the optical reaction layer can recombine with each other. As a result, asymmetric tunneling occurs, and thus a negative charge accumulates in the optical reaction layer. Thus, a threshold voltage Vₜₕ or a flat band V_{fb} of the optical reaction transistor can be varied. The variation of the threshold voltage Vₜₕ may correspond to the intensity of the light hv.

When the optical reaction transistor is not exposed to light hv, holes (h) are moved to the optical reaction layer from the gate electrode during programming (\textcircled{4}), and electrons (e) are moved from the p-type semiconductor substrate to the optical reaction layer by a programming voltage applied to the gate electrode (\textcircled{3}). Then, the holes (h) and the electrons (e) recombine with each other in the optical reaction layer, and the flat band V_{fb} of the optical reaction transistor is not significantly changed.

Meanwhile, in the current embodiment, data can be read from the semiconductor device by forming a potential difference between impurity regions of the optical reaction transistor and measuring a current flowing between the impurity regions. That is, the threshold voltage of the optical reaction transistor can be measured in this way. The intensity of light illuminated to the optical reaction transistor can be sensed using the measured threshold voltage.

FIG. 6 is a graph showing a relationship between a threshold voltage and a programming voltage of a semiconductor device according to an embodiment of the present invention. Referring to FIG. 6, the horizontal axis denotes the programming voltage applied to a gate electrode of the semiconductor device, and the vertical axis denotes the threshold voltage of the semiconductor device. The semiconductor device used to obtain the experimental results shown in FIG. 6 includes a tunnel insulation layer having a thickness of about 35 Å, a GaN layer having a thickness of 100 Å, and a hafnium layer having a thickness of 200 Å. As explained in FIG. 5, due to electrons accumulated in an optical reaction layer of the semiconductor device, the threshold voltage increases with the programming voltage in the case where light is illuminated to the semiconductor device. However, in the case where light is not illuminated to the semiconductor device, the threshold voltage does not change.

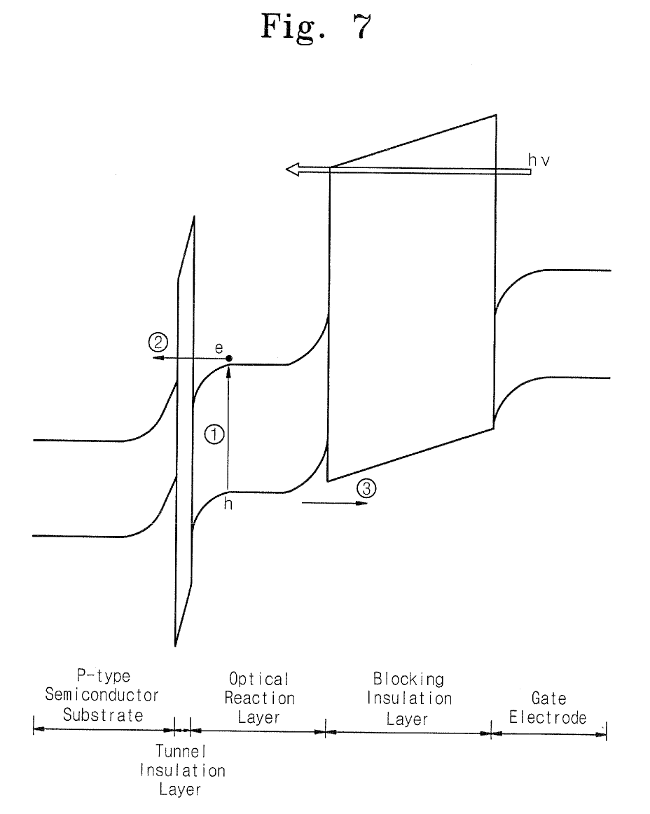

FIG. 7 is an energy band diagram for explaining a method of erasing data from a semiconductor device according to an embodiment of the present invention. Referring to FIG. 7, the semiconductor device includes an optical reaction transistor and has the same elements as the semiconductor device illustrated in FIG. 5. An erasing voltage (a negative voltage) is applied to the gate electrode of the optical reaction transistor. When the optical reaction transistor is exposed to light hv, pairs of electrons (e) and holes (h) are generated in the optical reaction layer (\textcircled{1}). The electrons (e) are moved to the p-type semiconductor substrate by tunneling since the tunnel insulation layer is thin (\textcircled{2}). The holes (h) are moved from the optical reaction layer to the gate electrode by tunneling caused by the erasing voltage applied to the gate electrode (\textcircled{3}). Electrons from the conduction band of the gate electrode are effectively blocked from entering the optical reaction layer by the blocking insulation layer. Also, holes from the valence band of the p-type semiconductor substrate are effectively blocked from entering the optical reaction layer by the tunnel insulation layer. As a result, asymmetric tunneling does not occur during the erasing operation, and thus electrons (e) do not accumulate in the optical reaction layer.

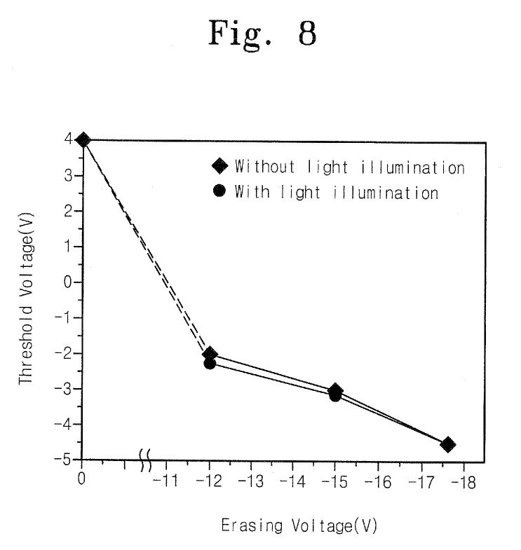

FIG. 8 is a graph showing a relationship between a threshold voltage and an erasing voltage of a semiconductor device according to an embodiment of the present invention. Referring to FIG. 8, the horizontal axis denotes the erasing voltage applied to a gate electrode of the semiconductor device, and the vertical axis denotes the threshold voltage of the semiconductor device. The threshold voltage of the semiconductor device decreases in reverse proportion to the erasing voltage regardless of light illuminated to the semiconductor device.

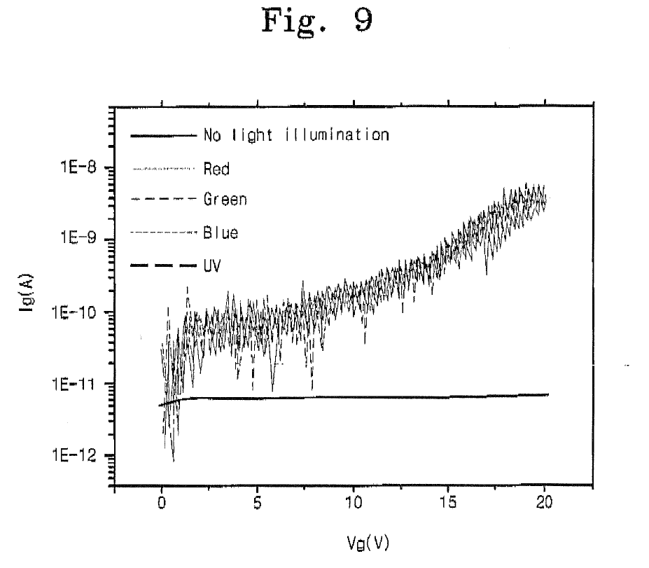

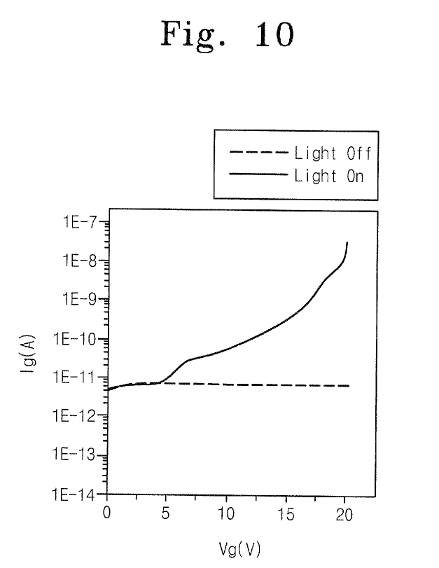

FIG. 9 is a graph showing tunneling current curves for the cases where a semiconductor device is illuminated and not illuminated, respectively. Referring to FIG. 9, the vertical axis denotes a tunneling current I_{g}, and the horizontal axis denotes a gate voltage V_{g}. When the semiconductor device is not illuminated, the tunneling current I_{g} is constant until the gate voltage V_{g} increases to a predetermined level. When the semiconductor device is illuminated, the tunneling current I_{g} increases in proportion to the gate voltage V_{g}. For example, when the gate voltage V_{g} increases from 0 V to 20 V, the tunneling current I_{g} increases approximately a thousand times. The tunneling current I_{g} increases at the same rate for all frequencies of illumination.

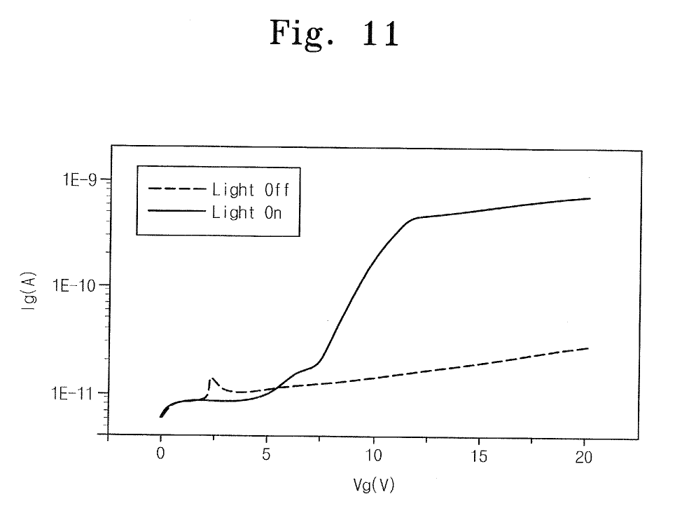

FIGS. 10 and 11 are graphs showing tunneling current curves for the case where an optical reaction layer is formed of GaN and the case where an optical reaction layer is formed of ZnO, respectively. In FIGS. 10 and 11, solid lines denote the case where the semiconductor device is illuminated, and dashed lines denote the case where the semiconductor device is not illuminated. Referring to FIGS. 10 and 11, the vertical axis denotes a tunneling current I_{g}, and the horizontal axis denotes a gate voltage V_{g}. When the semiconductor device is not illuminated, the tunneling current I_{g} of the GaN optical reaction layer and the ZnO optical reaction layer is substantially constant until the gate voltage V_{g} increases to a predetermined level because of a deep quantum well. When the semiconductor device is illuminated, the tunneling current I_{g} of the GaN optical reaction layer and the ZnO optical reaction layer increases in proportion to the gate voltage V_{g}.

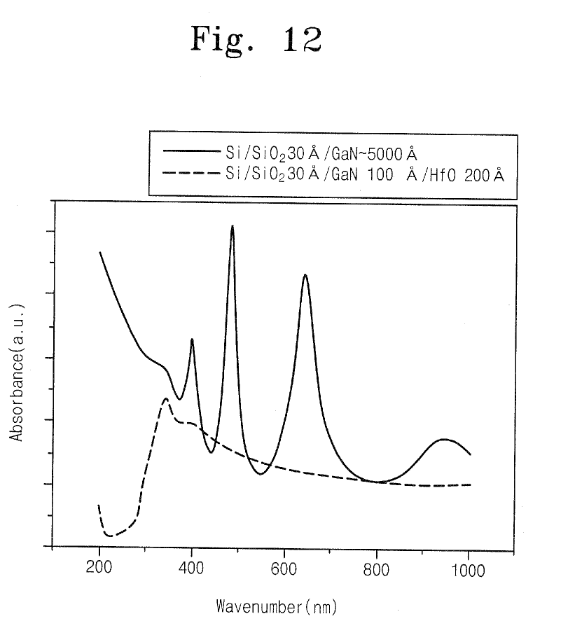

FIG. 12 is a graph illustrating an optical absorbance of an optical reaction layer formed of GaN with respect to wavelengths of light according to an embodiment of the present invention. Referring to FIG. 12, the horizontal axis denotes the wavelength of light, and the vertical axis denotes an optical absorbance. FIG. 12 illustrates the optical absorbance of the GaN optical reaction layer. An optical reaction transistor used for obtaining the graph of FIG. 12 includes a silicon oxide layer formed on a semiconductor substrate, the GaN optical reaction layer formed on the silicon oxide layer, and a hafnium oxide layer formed on the GaN optical reaction layer. The silicon oxide layer has a thickness of about 30 Å, and the hafnium oxide layer has a thickness of about 200 Å. In FIG. 12, a solid line denotes the case where the GaN optical reaction layer has a thickness of about 5000 Å, and a dashed line denotes the case where the GaN optical reaction layer has a thickness of about 100 Å. The GaN optical reaction layer absorbs light in a wide wavelength range from ultraviolet to visible. Therefore, light having any wavelength can be used for programming according to the present invention.

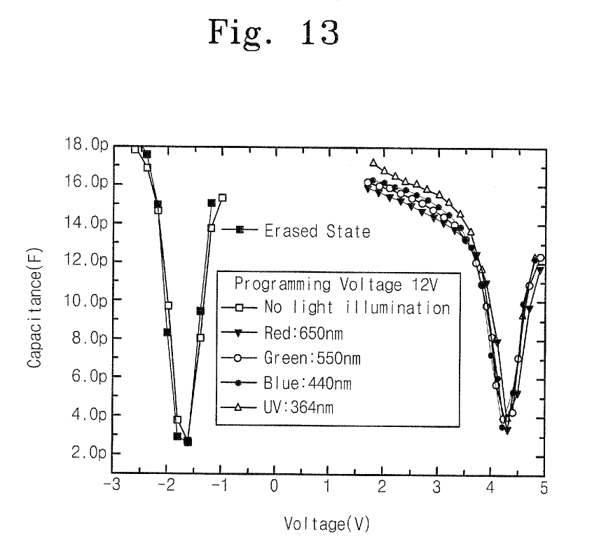

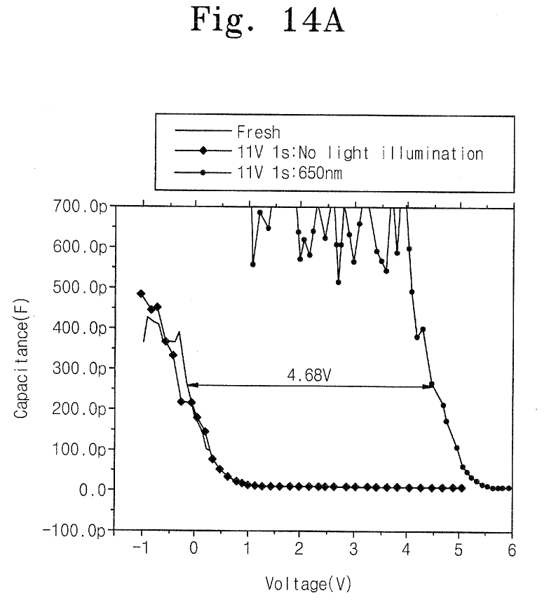

FIG. 13 is a graph illustrating capacitance-voltage (C-V) curves of a GaN optical reaction layer according to an embodiment of the present invention.

Referring to FIG. 13, the horizontal axis denotes a voltage applied to the GaN optical reaction layer, and the vertical axis denotes a capacitance. C-V curves drawn on the left side of FIG. 13 denote an erased state and a programming state without light illumination. C-V curves drawn on the right side of FIG. 13 denote programming states with light illumination. A programming voltage was 12 V, and red light having a wavelength of 650 nm, green light having a wavelength of 550 nm, blue light having a wavelength of 440 nm, and ultraviolet light having a wavelength of 364 nm were illuminated on the GaN optical reaction layer. The C-V curve drawn in the erased state is almost the same as that drawn in the case where light is not illuminated. That is, when light is not illuminated, the threshold voltage does not change. When light is illuminated, variations in threshold voltage are substantially the same for all wavelengths of the light.

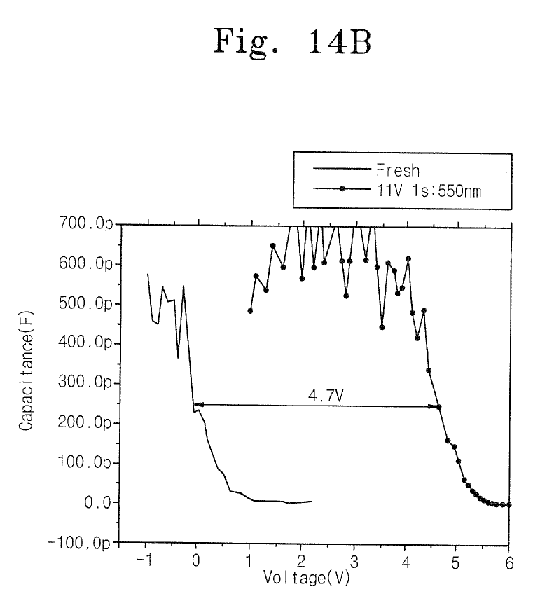

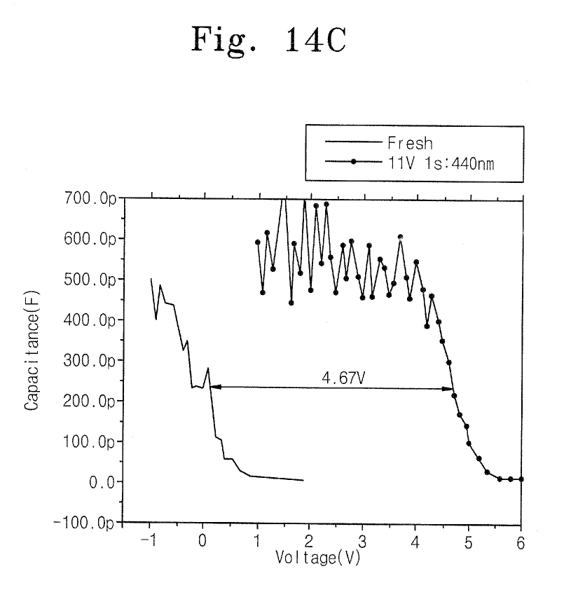

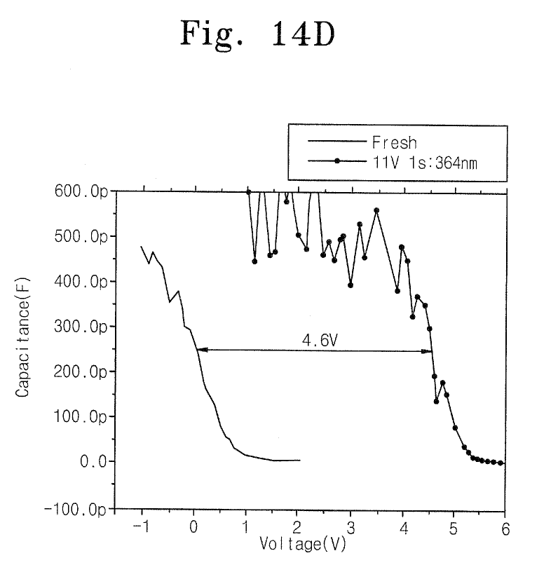

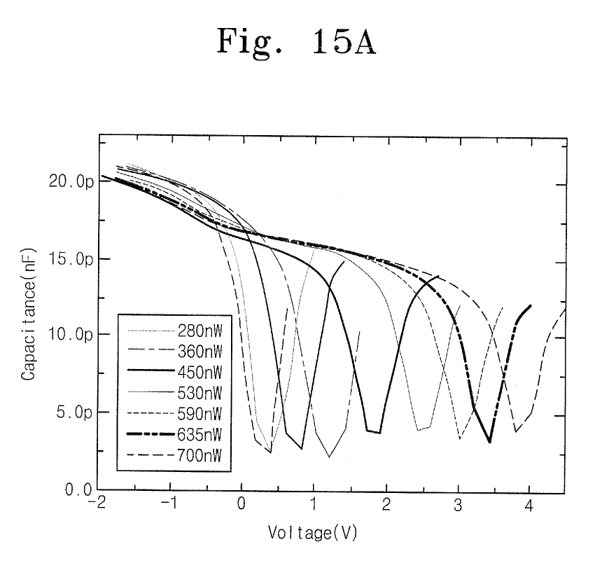

FIGS. 14A through 14D are graphs illustrating variations in threshold voltage with respect to wavelengths of light. In FIGS. 14A through 14D, the vertical axes denote capacitances, and the horizontal axes denote voltages. In FIG. 14A, red light having a wavelength of 650 nm is illuminated, and in FIG. 14B, green light having a wavelength of 550 nm is illuminated. In FIG. 14C, blue light having a wavelength of 440 nm is illuminated, and in FIG. 14D, ultraviolet light having a wavelength of 364 nm is illuminated. The gate voltage is 11 V. When light is not illuminated, the threshold voltage does not change as compared with an erased state. The reason for this is that electrons moved from a semiconductor substrate recombine with holes flowing from a gate electrode, such that charges do not build up in the optical reaction layer. The threshold voltage is about 4.7 V for almost all the wavelengths when light is illuminated as compared with the erased state or the case where light is not illuminated.

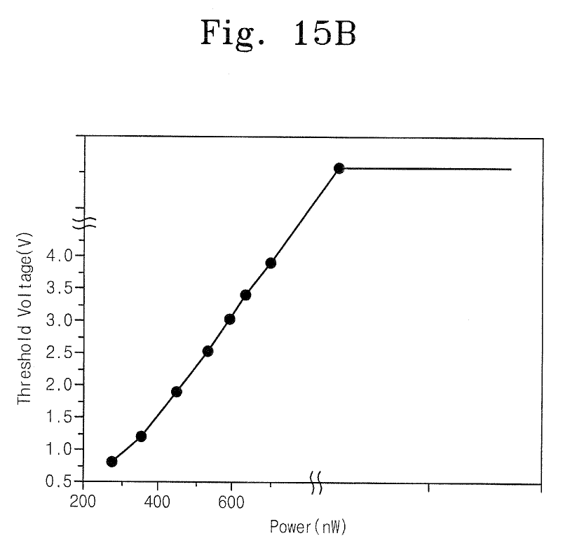

FIGS. 15A and 15B are graphs for explaining variations in threshold voltage with respect to the intensity of light. Referring to FIG. 15A, the vertical axis denotes a capacitance, and the horizontal axis denotes a voltage. The threshold voltage increases in proportion to the intensity of light. The reason for this is that more electrons are accumulated in an optical reaction layer in proportion to the intensity of light, thereby increasing the threshold voltage. Referring to FIG. 15B, the vertical axis denotes variations in threshold voltage, and the horizontal axis denotes the intensity of light. Red light having a wavelength of 650 nm is illuminated. Generally, the saturation level of a semiconductor device is 3000 electrons/μm. However, the semiconductor device of the current embodiment has a higher saturation level of about 45000 electrons/μm.

The semiconductor device of the current embodiment has a quantum efficiency (Q.E.) of 80% or more. The Q.E is a ratio of the number of electrons generated per unit time to the number of photons incident per unit time, as shown in Equation 1.

Q.E.=(ΔI/q)/(W/(hc/λ))=(ΔI·hc)/(q·W·λ) [Equation 1]

W: optical power [J/s]
hc/λ: the energy of a photon [J]
ΔI: a current difference between the cases where light is illuminated and not illuminated
q: quantity of electric charge

In Equation 1, W/(hc/λ) denotes the number of photons incident per unit time, and ΔI/q denotes the number of electrons generated per unit time. The semiconductor device of the present invention has a high Q.E. as compared with a typical semiconductor device having a Q.E. of about 40%.

According to some embodiments of the present invention, the threshold voltage of the optical reaction transistor increases owing to electrons accumulated in the optical reaction layer. Furthermore, the data retention time of the semiconductor device increases since the optical reaction layer includes a material having a high electron affinity. In addition, the endurance of the semiconductor device can increase. Moreover, the saturation level of the semiconductor device can increase and the Q.E. of the semiconductor device can increase to about 80%. Therefore, a smaller pixel unit can be formed using the semiconductor device of the present invention.

Embodiments of the present invention provide semiconductor devices including an optical reaction transistor, wherein the optical reaction transistor includes: a semiconductor substrate; a tunnel insulation layer formed on the semiconductor substrate; an optical reaction layer formed on the tunnel insulation layer; a blocking insulation layer formed on the optical reaction layer; and a gate electrode formed on the blocking insulation layer.

In some embodiments, the optical reaction layer may include a photoreactive charge trap layer. The optical reaction layer may include a material having an electron affinity greater than that of the semiconductor substrate. The optical reaction layer may include GaN or ZnO. The optical reaction layer may include nano crystals.

In other embodiments, the blocking insulation layer may include SiO2, HfO, ZrO, LaAlO, or AlO. The gate electrode may include a light-transmissive material. The light-transmissive material may include ITO or ZnO.

In still other embodiments, the optical reaction layer may extend above the semiconductor substrate under the gate electrode.

In even other embodiments, the semiconductor device may further include a pair of impurity regions formed in regions of the semiconductor substrate close to the gate electrode.

In yet other embodiments, a plurality of optical reaction transistors may be arranged in the semiconductor device, and the impurity regions may be shared by neighboring optical reaction transistors.

In other embodiments of the present invention, methods of driving the semiconductor device include: illuminating the optical reaction transistor with light so as to create electron-hole pairs in the optical reaction layer; and applying a programming voltage to the gate electrode to move the holes to the semiconductor substrate and trap the electrons in the optical reaction layer so as to change a threshold voltage of the optical reaction transistor.

In some embodiments, the programming voltage may cause the holes to move to the semiconductor substrate by tunneling but not allow the electrons to move to the gate electrode by tunneling.

In other embodiments, the change of the threshold voltage may correspond substantially to an intensity of the light.

In still other embodiments, the threshold voltage of the optical reaction transistor may be detected by forming an electrical potential difference between the impurity regions and measuring a current flowing between the impurity regions. The intensity of the light illuminated to the optical reaction transistor may be sensed using the detected threshold voltage of the optical reaction transistor.

In even other embodiments, the method may further include applying an erasing voltage to the gate electrode to move the holes to the gate electrode and move the electrons to the semiconductor substrate so as to remove the electrons trapped in the optical reaction layer of the optical reaction transistor.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor device comprising an optical reaction transistor, wherein the optical reaction transistor comprises:
a semiconductor substrate;
a tunnel insulation layer on the semiconductor substrate;
an optical reaction layer on the tunnel insulation layer;
a blocking insulation layer on the optical reaction layer; and
a gate electrode on the blocking insulation layer.

2. The semiconductor device of claim 1, wherein the optical reaction layer comprises a photoreactive charge trap layer.

3. The semiconductor device of claim 1, wherein the optical reaction layer comprises a material having an electron affinity greater than that of the semiconductor substrate.

4. The semiconductor device of claim 1, wherein the optical reaction layer comprises GaN or ZnO.

5. The semiconductor device of claim 1, wherein the optical reaction layer comprises nano crystals.

6. The semiconductor device of claim 1, wherein the blocking insulation layer comprises SiO₂, HfO, ZrO, LaAlO, or AlO.

7. The semiconductor device of claim 1, wherein the gate electrode comprises a light-transmissive material.

8. The semiconductor device of claim 7, wherein the light-transmissive material comprises ITO or ZnO.

9. The semiconductor device of claim 1, wherein the optical reaction layer extends above the semiconductor substrate adjacent to the gate electrode.

10. The semiconductor device of claim 1, further comprising a pair of impurity regions disposed in the semiconductor substrate.

11. The semiconductor device of claim 10, wherein a plurality of optical reaction transistors are disposed in the semiconductor substrate, and the impurity regions are shared by neighboring optical reaction transistors.

12. A method of driving the semiconductor device of claim 10, the method comprising:
illuminating the optical reaction transistor so as to create electron-hole pairs in the optical reaction layer, each of the electron-hole pairs comprising an electron and a hole; and
applying a programming voltage to the gate electrode to move the holes to the semiconductor substrate and trap the electrons in the optical reaction layer so as to change a threshold voltage of the optical reaction transistor.

13. The method of claim 12, wherein the programming voltage causes the holes to move to the semiconductor substrate by tunneling but does not allow the electrons to move to the gate electrode by tunneling.

14. The method of claim 12, wherein the change of the threshold voltage corresponds substantially to an intensity of the illumination.

15. The method of claim 14, wherein the threshold voltage of the optical reaction transistor is detected by forming an electrical potential difference between impurity regions of the optical reaction transistor and measuring a current flowing between the impurity regions.

16. The method of claim 15, wherein the intensity of the illumination to the optical reaction transistor is sensed using the detected threshold voltage of the optical reaction transistor.

17. The method of claim 12, further comprising applying an erasing voltage to the gate electrode to move the holes to the gate electrode and move the electrons to the semiconductor substrate so as to remove the electrons trapped in the optical reaction layer of the optical reaction transistor.

18. A method of detecting illumination on a semiconductor device, the method comprising:
illuminating the semiconductor device, wherein the semiconductor device comprises:
a tunnel insulation layer on a semiconductor substrate;
an optical reaction layer on the tunnel insulation layer;
a blocking insulation layer on the optical reaction layer; and
a gate electrode on the blocking insulation layer; and
detecting a change in threshold voltage of the semiconductor device corresponding to the illumination.

19. The method of claim 18, wherein the change in threshold voltage corresponds to an intensity of the illumination.

20. The method of claim 18, wherein the optical reaction layer comprises a material having a higher electron affinity than the semiconductor substrate.

21. The method of claim 18, wherein the gate electrode comprises a light-transmissive material.

22. The method of claim 18, wherein the optical reaction layer extends along the semiconductor substrate to a greater extent than the gate electrode and wherein the gate electrode does not include a light-transmissive material.

23. The method of claim 18, wherein the change in threshold voltage does not correspond to a wavelength of the illumination.

24. The method of claim 18, wherein detecting the threshold voltage comprises measuring a current flowing between impurity regions in the semiconductor device.
